(19) United States
(12) Patent Application Publication
(10) Pub. No.: US 2015/0304761 A1
(43) Pub. Date: Oct. 22, 2015

(54) Noise abatement system for dental procedures

(71) Applicants: Peman Montazemi, Aliso Viejo, CA (US); Shaghayegh Zekavati, Aliso Viejo, CA (US); Massimo Mitolo, Aliso Viejo, CA (US)

(72) Inventors: Peman Montazemi, Aliso Viejo, CA (US); Shaghayegh Zekavati, Aliso Viejo, CA (US); Massimo Mitolo, Aliso Viejo, CA (US)

(21) Appl. No.: 14/495,906

(22) Filed: Sep. 25, 2014

Related U.S. Application Data
(60) Provisional application No. 61/883,199, filed on Sep. 27, 2013.

(51) Int. Cl. H04R 1/10; H03G 3/32; G10K 11/00

(52) U.S. Cl. CPC H04R 1/1083; G10K 11/002; H04R 1/1025; H03G 3/32

(57) ABSTRACT

A noise abatement system for dental procedures conceived to protect the hearing of dental operators (dentists, dental hygienists, dental assistants dental technicians and/or any other dental staff member in the dental operatory) as well as of patients, comprises a pair of headphones composed of one (1) left and one (1) right phone [1] connected to each other via a strap [2], an audio signal processor (ASP) [7] with associated circuitry, a remote operator on/off talk button [14] and a voltage source charging station [2530]. The user of the system can toggle an operator/patient switch [8] in the casing of the headphones to switch between operator mode and patient mode. In operator mode, high-frequency noise from dental tools is captured by one (1) left and one (1) right microphone [3], is filtered out by a noise-abating filter [16], as a part of the ASP, and only frequencies from speech signals are allowed to the operator through a pair of speakers [4] mounted in the casing of the phones. In patient mode, all noise is filtered out by the audio signal processor from the surrounding environment and, therefore, no noise is allowed to the patient through the two left and right speakers [4]; however, if an operator enables the operator on/off talk button [20], the patient will be able to hear speech frequencies from any operator in the surrounding environment. Thus, a high-frequency noise-abating system is provided to dental practice's, practitioners and technicians that prevent them, as well as patients, from being exposed to unwanted noise from dental tools. At the same time, dental staff members and technicians can communicate among each other during the dental procedure, or operation of dental tools, while the pair of headphones is functioning; they can also communicate with the patient by pushing an operator on/off talk button [14]. This system also allows each user to mix in an auxiliary audio signal from an external audio source [15]; when in patient mode, this auxiliary audio signal gets muted when the operator pushes the operator on/off talk button [20] in order to talk to the patient. Last, this system can be recharged by resting the pair of headphones onto a charging station [29].

### CROSS-REFERENCE TO RELATED APPLICATIONS

This application claims the benefit of provisional patent application No. 61/883,199, filed 2013 Sep. 27 by inventors Peman Montazemi and Massimo Mitolo.

### FEDERALLY SPONSORED RESEARCH

Not Applicable SEQUENCE LISTING OR PROGRAM

Not Applicable

### BACKGROUND

1. Field of Invention

This invention relates to a headphones system, specifically to such system which is used in dental procedures by dental staff members and the patient to abate noise from dental tools and other apparatus present in dental operatories while allowing communication among dental staff members and between such members and the patient.

2. Prior Art

This invention consists of noise-abating headphones specifically designed for dental procedures, which usually employ equipment emitting high-frequency noise, which may harm the dental staff, as well as patients. Dental procedures can be noisy due to the nature of dental tools and dental instruments. This constant high-frequency noise can affect the hearing capability of any dental staff member and can also be non-compliant with OSHA regulations regarding the maximum permissible noise exposure levels for workers in a dentist office. Over time, this can cause hearing loss, as well as psychological stress, to the dentist office staff, with serious negative effects on the quality of life and the performance of the operators. In addition, this harsh environment can make patients uncomfortable, even fearful, as they are normally awake during dental procedures. A healthier environment for both operators and patients can be reached by shielding them from the noise coming from dental equipment; this can be achieved by providing special headphones, filtering out the background noise, but allowing the recognition of speech among dental staff members, or between operators and patient. The same headphones may allow the introduction of auxiliary audio signals (e.g. music, soothing sounds, radio, TV or any external device capable of generating an audio signal) with a calming or distracting effect for the patient of any age.

Current use of various acoustic techniques has so far failed to provide a quiet environment for both operators and patients. Various high-frequency noises from dental tools such as drills, suction system, air compressors, water pick, ultrasonic scaler, and more are variable in frequency (i.e. pitch gets higher or lower), in amplitude (i.e. noise gets louder or quieter) and in direction (i.e. operator, patient and/or dental tools are moved in space and in time). On one hand, dental tools cannot get any quieter and on the other hand, current acoustic technologies can hardly abate the high-frequency sounds present emitted during dental procedures.

Both U.S. Pat. No. 4,977,600 to Ziegler (1990), W.O. Pat. No. 2002/100287 A2 to Saban and Zilberman (2002) and U.S. Pat. No. 5,133,017 to Barnes, Cain, Chait and Dye (1992) show noise suppression systems for personal/patient seat. These seats have a pair of noise-suppressing speakers placed in the headrest of the chair which, based on the noise coming from the surrounding environment, generate a noise-suppressing signal that creates a quiet zone in the space surrounding the ears of the user/patient. While both systems provide a quiet zone to the patient, neither are suited to provide a quiet zone for the dental operators. Similar patents are: U.S. Pat. No. 8,130,987 to Kaneda, Kishi and Shiina (2012) and U.S. Pat. No. 8,480,176 to Yamada (2013). In addition, for all the above patents, the effective communication with the patients is not allowed.

E.P. Pat. No. 0438384 A1 to Ambrosio (1991) shows a dentist chair with an earpiece sound diffusion system. This sound diffusion system comprises a music player therewith an amplifier and sound level adjusting unit. The sound diffusion system is associated with the dentist chair so that the earpieces are arranged on two sides of a headrest of the chair and provide music to the patient during the dental procedure. However, this system does not provide any sound diffusion to the dental staff member nor it presents any active means of high-frequency noise suppression for the benefit of both dental staff members and patient, i.e. playing music to the patient does not guarantee that the high-frequencies sounds generated by dental tools will be cancelled.

U.S. Pat. No. 5,692,056 to Gardner (1997) and U.S. Pat. No. 6,466,673 to Hardy (2002) show an intracranial noise suppression apparatus. These devices cancel the part of the noise that is emitted to the auditory nerve via conduction through the cranial bones. While these devices may eliminate a portion of the noise coming from dental tools transmitted to the patient through bone conduction, they fail to cancel the noise transmitted to both dental staff members and patient through the air. Another similar patent is U.S. Pat. No. 8,433,083 to Abolfathi and Spiridigliozzi (2013).

U.S. Pat. No. 5,737,433 to Gardner (1998) shows a sound environment control apparatus which allows a user, by operating a remote control unit, to selectively suppress any of all of multiple noises in his or her environment, or selectively listen to any of these while suppressing all other sounds. This apparatus requires the user to place sound detectors at each interfering sound source that the user may wish to be able to control, i.e. suppress or enhance. However, this system is not practical as no object, such as a sound detector, can be placed near the various sound sources present in a dental operatory. These sound sources correspond to the dental drill, the suction system, etc., which are all employed to the area of the mouth of the patient, which is a confined space with low visibility, which does not allow for any additional device, but the dental tools to be present.

U.S. Pat. No. 6,118,878 to Jones (2000) shows an active noise cancellation system for headphones with strategic microphone placement to detect a signal more similar to that incident upon the eardrum of the user. While this system provides more effective noise cancellation and improved stability, it does not allow communication between a dental staff member and a patient while in use.

U.S. Pat. No. 6,728,385 to Kvaløy, Ottesen, Henriksen, Stensby, Sørsdal, Pettersen and Svean (2004) and U.S. Pat. No. 7,246,058 B2 to Burnett (2007) show a voice detection system and discrimination system. While both devices provide efficient means to detect voice, the first device must be worn in an in-ear fashion, which is not practical or comfortable for both dental staff member and patient if worn for prolonged periods of time, besides being non-compliant with OSHA regulations about hygiene; the second patent requires not one, but two microphones to calculate the difference in signal gain between portions of the received acoustic signals, which increases the complexity of the system, thus decreasing its reliability. A similar patent is U.S. Pat. Appl. Pub. No. 2007/0189544 to Rosenberg (2007).

U.S. Pat. No. 6,975,158 to Sekimoto (2005) shows a noise canceling circuit that uses a low-pass filter to eliminate high-frequency component contained in an input signal. While this method is effective in canceling high-frequency components of narrow and wide widths, it fails to cover all audible high-frequencies of variable amplitude in time and coming from various directions, such as noise from dental tools.

U.S. Pat. No. 7,003,099 to Zhang and Pai (2006) shows a system that cancels acoustic echo and suppresses noise. While an array microphone combined with signal processing can be effective in removing echo and suppressing noise in communication systems and voice recognition devices, it cannot be used in the dental operatory, as the head of operators and patients should be placed between the microphones of the array microphone, which would block the beam formed by the array microphone to function normally. Similar patents to this invention are: U.S. Pat. No. 6,738,482 to Jaber (2004), U.S. Pat. No. 7,403,608 to Auvray, Le Tourneur and Thomas (2008), U.S. Pat. No. 7,415,372 to Taenzer and Spicer (2008) and U.S. Pat. No. 8,315,400 to Goldstein, Usher, Boillot and McIntosh (2012).

U.S. Pat. No. 7,171,008 to Elko (2007) shows a method to reduce noise in audio systems which can be used to reduce turbulent wind-noise resulting from wind or other airjets blowing across the microphones. While this method is useful at reducing wind noise, such noise type is not present in a typical dental operatory.

U.S. Pat. No. 7,215,766 to Wurtz (2007) shows a headset with auxiliary input jack(s) for cell phone and/or other devices. While this active noise reduction system provides means for successfully integrating more than one audio source, such as a primary input signal and an auxiliary audio signal, the latter requires an auxiliary port for connection to an output of at least one device. The invention herein presented does not require any port of connection to receive the auxiliary audio signal from an external audio source. This action is done remotely.

D.E. Pat. No. 102007054051 to Schmitt-Bylandt and Tannhäuser (2009) shows a method for reducing anxiety and stress of patient during dental treatment. This system is conceived to reduce anxiety by displaying an image of the patient's mouth to him/her; this solution can be counterproductive (i.e. increase patient's anxiety instead). Additionally, the background noise is not filtered or removed, but only attenuated.

U.S. Pat. No. 7,817,803 to Goldstein (2010) shows methods and devices for hearing damage notification and intervention. This method monitors hearing health and includes: a first acoustic sound pressure level due to an ambient audio signal; a second acoustic sound pressure level due to an emitted audio signal from a speaker; finally calculates a total sound pressure level dosage and sending a notification signal when total sound pressure level dosage is greater than a threshold value. While this system may be useful in a dental operatory, it fails to filter out undesired high-frequency noise coming from dental tools. A similar patent is U.S. Pat. No. 8,218,784 to Schulein, Shaw and Brown (2012).

U.S. Pat. No. 7,970,159 to Kleinschmidt, Pavlotsky and Sapiejewski (2011) shows a noise reducing headset with a pair of earcups among other components; one of the earcups has a battery door that may be opened to allow insertion and removal of the battery and covered by a yoke assembly when the headset is worn by the user, with the battery fully seated in the earcup. While this headset system offers a list of components similar to the presented invention, it fails to have a voltage source that is rechargeable through connection to a remote charging station. Additional patents related to the active noise reduction technique are: U.S. Pat. No. 7,277,722 to Rosenzweig (2007), U.S. Pat. Appl. Pub. No. 2009/0034748 to Sibbald (2009), W.O. Pat. 2009/135674 to O′loughlin (2009), W.O. Pat. No. 2010/107528 to Pan (2010), U.S. Pat. No. 8,073,150 to Joho and Carreras (2011), W.O. Pat. No. 2011/129934 to Hopkins (2011), U.S. Pat. No. 8,189,803 to Bergeron, Crump and Gauger (2012) and U.S. Pat. No. 8,194,873 to Pan, Cheng and Salvador (2012). The active noise reduction technique has proven to work only on cyclic low-frequency noise (e.g. airplane engine, ambient noise). Dental tools generate high-frequency noise which cannot be eliminated using this technique.

U.S. Pat. No. 8,077,874 to Sapiejewski (2011) shows an active noise cancellation system for headphones with strategic microphone placement to improve phase margin in the feedback circuit. The said headset system uses active noise reduction technique which again, is primarily known to work on low-frequency cyclic noise but, not on high-frequency non-cyclic noise such as the one coming from dental tools. The presented invention uses passive filtering technique instead.

“Hearing Problems Among Dental Personnel” by Khalid A. Al Wazzan et al., JPDA Vol. 14 No. 4 October-December 2005 concludes that hearing problems among dental personnel are not of a severe nature, that hearing problems can happen due to dental field noise, that dental technicians are more prone to hearing problems than other dental personnel and that incidence of hearing problems increases with the increase of daily noise exposure. Their recommendations are that the dental field team should have ear protectors to reduce the hazards of dental field noise, particularly dental technicians and those who are exposed to dental noise for long periods daily. Therefore, the invention herein presented can be applicable to dental technicians as well.

### SUMMARY

This invention, noise-abating headphones for dental procedures, is made of a left and a right phone connected to each other via a strap. Each phone carries a microphone that captures noise from the surrounding environment, transmits it to an audio signal processor (ASP), which filters out unwanted high-frequency noise coming from dental tools; the filtered audio signal is then sent into the ears of the user through a left and a right speaker mounted within the said phones. An operator/patient switch turns the headphones functionality between operator mode and patient mode. In the operator mode, the audio signal processor is turned on and abates high-frequency dental field noise produced by dental tools, and allows speech frequencies from the surrounding environment to be heard by the user. In patient mode, the audio signal processor is off unless an external operator (e.g. dentist, dental hygienist, dental assistant, dental technician and/or any other dental staff member in the dental operatory) switches a remote operator on/off talk button to the on position, in which case the patient can hear speech frequencies from the surrounding environment, but not the unwanted high-frequencies from dental field noise. In addition, in both operator and patient modes, the user of these headphones can mix in an auxiliary audio signal coming from an external audio source (e.g. music, soothing sounds, radio, TV or any external device capable of generating an audio signal). Still further advantages will become apparent from a study of the following description and the accompanying drawings.

### DRAWINGS

### Figures

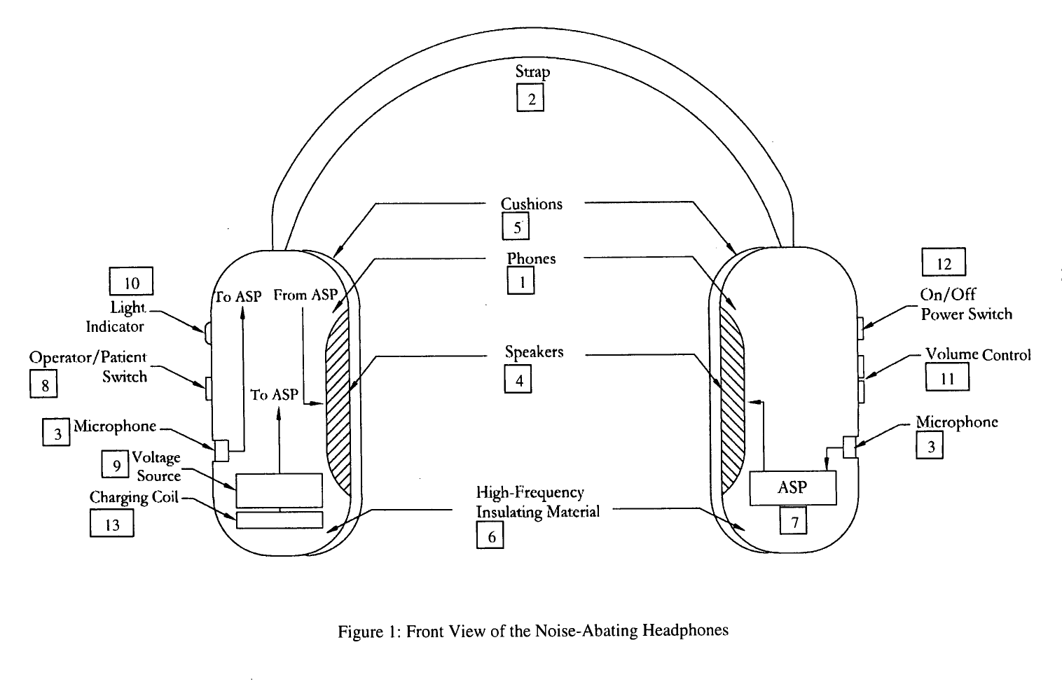

FIG. 1: Front View of the Noise-Abating Headphones

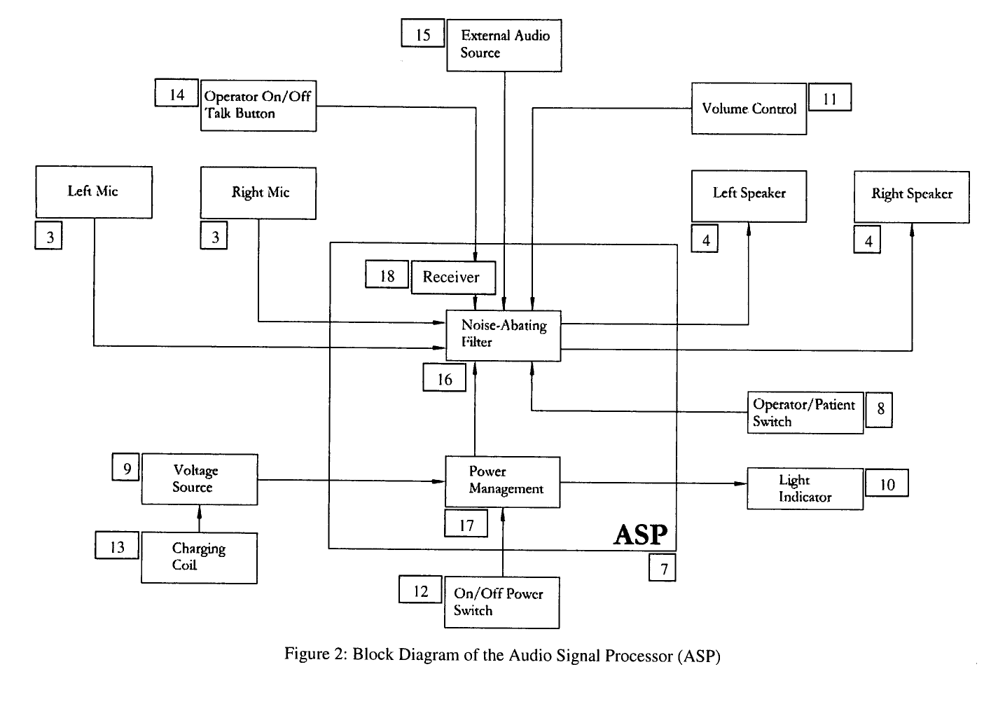

FIG. 2: Block Diagram of the Audio Signal Processor (ASP)

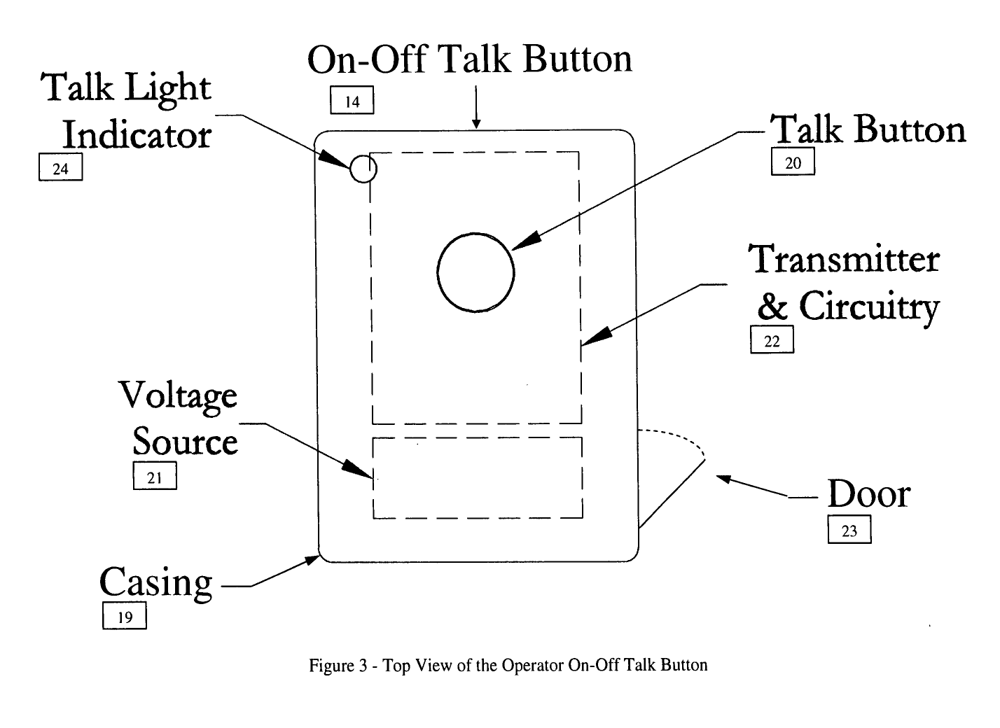

FIG. 3: Top View of the Operator On/Off Talk Button

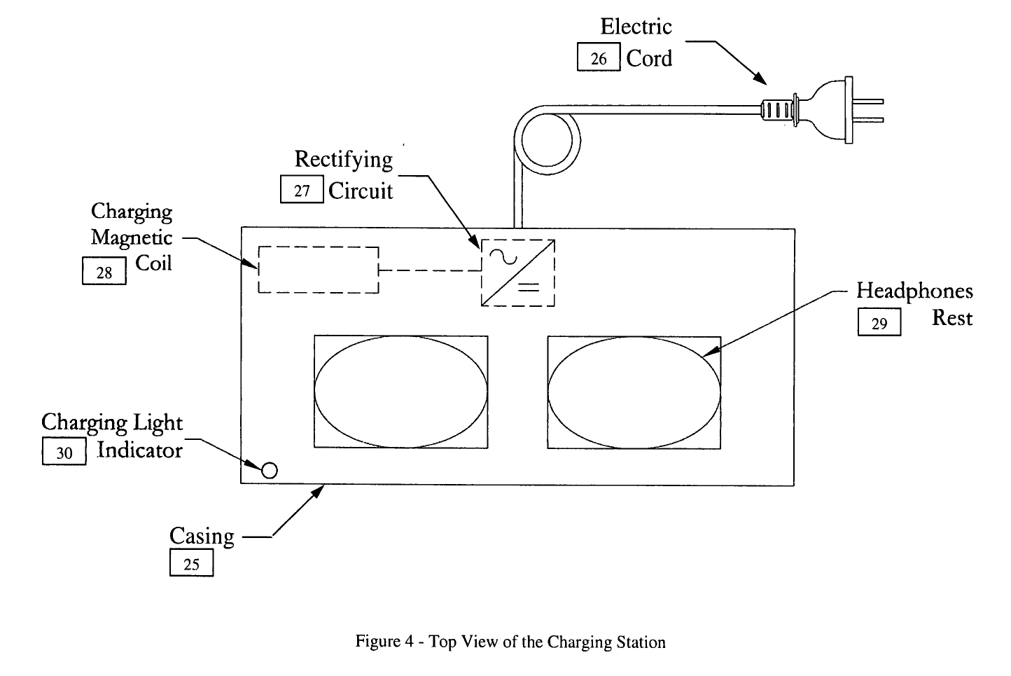

FIG. 4: Top View of the Charging Station

### REFERENCE NUMERALS

[1] Left and Right Phones
[2] Strap
[3] Left and Right Microphones
[4] Left and Right Speakers
[5] Left and Right Cushions
[6] High-Frequency Insulating Material
[7] Audio Signal Processor (ASP)
[8] Operator/Patient Switch
[9] Voltage Source of Pair of Headphones
[10] Light Indicator of Pair of Headphones
[11] Volume Control
[12] On/Off Power Switch
[13] Charging Coil of Pair of Headphones
[14] Operator On/Off Talk Button
[15] External Audio Source
[16] Noise-Abating Filter
[17] Power Management
[18] Receiver
[19] Casing of Operator On/Off Talk Button
[20] Talk Button
[21] Voltage Source of Operator On/Off Talk Button
[22] Transmitter and Circuitry
[23] Door
[24] Talk Light Indicator
[25] Casing of Charging Station
[26] Electric Cord
[27] Rectifying Circuit
[28] Charging Magnetic Coil
[29] Headphones Rest
[30] Charging Light Indicator

### DETAILED DESCRIPTION

FIG. 1 displays a front view of the pair of noise-abating headphones comprising two phones [1] covering the ears of the user, one strap [2] mechanically connecting the phones, two external microphones [3], two internal speakers [4], two padded cushions [5], two phones containing high-frequency insulating material [6], one internal audio signal processor with associated circuitry [7], one operator/patient switch [8], one internal voltage source [9], one voltage source light indicator [10], one volume control [11], one on/off power switch [12] and one charging coil [13].

FIG. 2 displays a block diagram of the audio signal processor (ASP) [7] comprising all inputs/outputs as well as internal functional blocks. In operator mode, the audio signal processor receives audio inputs from the two microphones [3], applies adequate filtering [16] to abate the high-frequency noise from dental tools, and outputs audio signals in speech frequency range from the surrounding environment to the ears of the user through the two speakers [4]. In patient mode, the ASP [7] is turned off and no noise is passed in to the user's ears through the speakers [4]. However, an operator on/off talk button [14] turns on the ASP and enables the user to hear audio signals in speech frequency range from the surrounding environment. Both operator and patient modes allow an auxiliary audio signal coming from an external audio source [15] to be mixed in. When the operator on/off talk button is in the on position and the operator/patient switch is in patient mode, the auxiliary audio signal is muted. The ASP [7] also has a power management unit [17] capable of governing power logic among the voltage source [9], on/off power switch [12], noise-abating filter [16] and light indicator [10]. As part of its associated circuitry, the ASP [7] also has a receiver [18] capable of receiving a triggering signal from the operator on/off talk button [14] when this one is enabled.

FIG. 3 displays a top view of the operator on/off talk button [14] which comprises one casing [19], one on/off talk button [20], one voltage source [21], one transmitter with associated circuitry [22], one sliding door to change the voltage source [23] and a talk light indicator [24] that turns on every time the operator on/off talk button is enabled. The operator on-off talk button can be either mounted onto the dental chair and be pressed by the operators' fingers or can be mounted into a foot switch that can be pressed by the operators' foot.

FIG. 4 displays a top view of the charging station which comprises one casing [25], one electric cord [26], one rectifying circuit [27], one charging magnetic coil [28], a headphones rest [29] where the pair of headphones can be rested on for charging and a charging light indicator [30].

### OPERATION

In operation, one uses the pair of noise-abating headphones (FIG. 1) with the operator/patient switch [8] in operator mode. In this mode, the operator can only hear audio signals in speech frequency range and the noise from various dental tools is abated.

In operation, one uses the pair of noise-abating headphones (FIG. 1) with the operator/patient switch [8] in patient mode. In this mode, the patient cannot hear any noise from the surrounding environment, especially the high-frequencies emitted from various dental tools. Also in this mode, an operator can press on a talk button [20] located on a remote operator on/off talk button [14] (FIGS. 2 and 3), which will enable the patient to hear audio signals in speech frequency range, but not the noise from various dental tools.

In both operator and patient modes, the user can mix in an auxiliary audio signal coming from an external audio source [15]. In patient mode, when the operator presses the talk button [20], the auxiliary audio signal is muted for both users. The user of this system can control the volume of the audio signals by using a volume control button [11].

In operation, the user can turn the pair of noise-abating headphones on or off by switching an on/off power switch [12].

Last, the pair of noise-abating headphones can be rested onto a charging station [25-30] (FIG. 4) to charge its voltage source [9] in case it has reached a low voltage level. When charging, the charging station's charging light indicator [30] turns red. When the voltage source [9] of the pair of noise-abating headphones (FIG. 1) is fully charged, the charging light indicator turns green.

1. A system for noise abatement of dental procedures that is primarily designed to protect the hearing of dental operators (e.g. dentist, dental hygienist, dental assistant, dental technician and/or any other dental staff member in the dental operatory, all hereafter called operators of the said system) and dental patients, includes a pair of headphones located on the head of each user
that is composed of one (1) left and one (1) right phone placed of the left and right ears of the user, and connected to each other via a flexible strap
wherein one (1) left and one (1) right microphone (hereafter called mics) are mounted within the casing of the said left and right phones, with a hole in each said casing in front of each mic allowing the latter to receive audio signals from the surrounding environment
wherein one (1) left and one (1) right speaker are mounted in the casing of the said left and right phones at the level of the user's ears; the inner surface of each said casing has a hole or several holes to let each said speaker provide audio signals to each ear of the user
wherein the casing of the said left and right phones is large enough to cover the left and right ears of the user
wherein the casing of the said left and right phones have a padded cushion in contact with the user's head surface to increase comfort while wearing the device and acoustic isolation with respect to high-frequency noise from the surrounding environment
wherein the walls of the said casing of the said left and right phones are made of high-frequency insulating material to provide acoustic isolation from the surrounding environment
wherein a noise-abating audio signal processor and associated audio signal processing circuitry (combination hereafter called audio signal processor or ASP) are mounted in the casing of the said pair of headphones; the ASP receives audio signals captured from the surrounding environment by the said pair of mics, processes them and sends the processed noise-abated audio signals to the user's ears through the said pair of speakers
wherein an operator/patient switch mounted in the casing of the said pair of headphones switches the said ASP between operator mode and patient mode; in operator mode, the said ASP allows the user to hear through the said pair of speakers all audible frequencies within speech range captured by the said pair of mics from the surrounding environment, whereas the rest of the frequencies, including high-frequency noise emitted by all dental apparatuses used by the operator (e.g. dental drill, suction system, air compressor, water pick, ultrasonic scaler and similar apparatus hereafter called dental tools) are filtered out; in patient mode, the headphones, covered in high-frequency insulating materials, filter out all sounds, including all audible frequencies within speech range, as well as noise emitted by dental tools, as the ASP is turned off
that, when the operator/patient switch is in the patient mode, an operator-controlled on/off talk button located on an external remote device transmits a triggering signal to the receiver that is part of the circuitry on board of the pair of headphones; the receiver then emits the triggering signal to the ASP, which in turn, enables the patient to hear through the said pair of speakers all audible frequencies in the speech range captured by the said pair of mics from the surrounding environment, yet still filtering out noise emitted by dental tools; when the operator/patient switch is in the operator mode, the operator on/off talk button has no effect on the ASP
wherein an independent direct-current constant voltage source (hereafter called voltage source) is mounted in the casing of the said pair of headphones; the said voltage source powers the said ASP and all electrically-connected components as part of the said pair of headphones
wherein a light indicator located on the external surface of the said pair of headphones displays the voltage source level to the user: the said light turns green when the said voltage source voltage level is adequate and red when the said voltage source voltage level is below a threshold and needs to be replaced or recharged; the status of the said light indicator is controlled by the said ASP, which monitors the voltage level of the voltage source
wherein an audio signal volume control button is located on the external surface of the said pair of headphones allowing the user to increase or decrease the audio signal volume level delivered by the said pair of speakers to the user's ears
wherein an on/off power switch is located on the external surface of the said pair of headphones allowing the user to turn on or off the power supply from the said voltage source to the ASP and associated circuitry; when the power on/off switch is in the on position, the said light indicator turns on based on the said light color scheme; when the power on/off switch is in the off position, the said light indicator turns off
that has a charging coil that receives magnetic energy from a charging station, converts the said energy to electric current which, in turn, charges the said voltage source.

2. An audio signal processor (ASP), according to claim 1,
that is mounted in the casing of the said pair of headphones and that receives inputs such as audio signals captured from the surrounding environment by the said pair of mics and provides noise-abated audio signals through the said pair of speakers to the ears of the user
that functions in operator mode or patient mode by toggling the said operator/patient switch; in operator mode, the noise-abating filter of the ASP filters the audio signals captured by the said pair of mics from the surrounding environment and produces a noise-abated audio signal within the speech frequency range through the said pair of speakers to the user's ears; in patient mode, the noise-abating filter of the ASP is turned off and no audio signal other than the auxiliary audio signal is sent to the user's ears through the said pair of speakers
that allows the patient to hear all audible frequencies from surrounding speech sounds as long as the said operator on/off talk button is in the on position and the operator/patient switch is in patient mode; when enabled, the operator on/off talk button sends a signal to the ASP on board of the patient's pair of headphones to turn it on, thereby enabling the speech frequencies to be heard by the patient
with its associated circuitry that are electrically powered by the said voltage source
that controls the functionality of the said voltage source light indicator
that controls the volume level of the outgoing audio signals from the said pair of speakers to the ears of the user; the increase or decrease of the volume level is received by the ASP from the said volume control button
that turns off as it stops receiving power from the said voltage source in case the said power on/off switch is in the off position; when the power on/off switch is in the on position, the ASP can be on or in sleep mode according to the functionality of the said operator/patient switch and the said operator on/off talk button
that automatically turns on from a sleep mode in case there is any high-frequency noise level above a threshold and accomplishes its noise-abating task according to the functionalities dictated by the said operator/patient switch and the said operator on/off talk button; this sleep mode functionality is intended to extend the lifetime of the said voltage source
that can be remotely programmed using an external computing device (e.g. computer) equipped with tuning software; the programming is focused on modifying the audio signal processing parameters of the ASP to obtain optimal functionality
that allows the user to mix in to the said noise-abated audio signal an auxiliary audio signal coming from a remote external audio source (e.g. music player, audio channel, TV, and/or any other apparatus capable of generating an audio signal); when the operator/patient switch is in patient mode, the auxiliary audio signal gets muted by the ASP when the operator on/off talk button is in the on position to allow the patient hear the speech sounds from the surrounding environment; the volume of the auxiliary audio signal is controlled via the said volume control buttons located on the casing of the said pair of headphones or from the external audio source itself if that capability is available
that in said operator mode, automatically detects, by processing audio signal captured from the said pair of microphones, a minimum threshold level in speech frequencies that, if surpassed, will wake up the ASP and transmits the said speech frequencies through the said pair of speakers to the ears of the user; this threshold detection functionality is intended to extend the lifetime of the said voltage source and avoid user to hear sounds through the said pair of speakers in absence of speech frequencies in the surrounding environment
that has a power management capability that integrates the voltage source, on-off power switch, noise-abating filter and light indicator into the functionality of the said ASP
that when the operator/patient switch is in patient mode, upon receiving a triggering signal from a receiver, enables the user to hear through the pair of speakers all audible frequencies in the speech range captured by the said pair of mics from the surrounding environment, yet still filtering out noise emitted by dental tools; when the operator/patient switch is in the operator mode, the operator on/off talk button has no effect on the ASP.

3. An operator on/off talk button, according to claims 1 and 2,
that allows the operator to talk to the patient when the said operator on/off talk button is in the on position; the button works only if the operator/patient switch is in patient mode
that has a casing (separate from the casing of the said pair of headphones) comprising the said talk button, a voltage source, a transmitter with associated circuitry, a door and a talk light indicator
wherein a talk button that can be pressed to enable the talk functionality between operator and patient
which talk button can be either mounted onto the dental chair and be pressed by the operators' fingers or be mounted into a foot switch which can be pressed by the operators' foot
wherein a voltage source provides power to the said transmitter and associated circuitry
wherein, upon pressing the said talk button, the said transmitter and associated circuitry sends a triggering signal to the receiver on board of the pair of headphones in patient mode
that has a door in its said casing that can be opened by the user in order to replace the voltage source in case this one reaches a low voltage level that would impeach the operator on/off talk button to function normally
wherein a talk light indicator located on the external face of the said casing is turned on every time the talk button is pressed by the user; the said talk light indicator is powered by the said voltage source through the said circuitry.

4. A charging station, according to claims 1 and 2,
that allows recharging the voltage source of the said pair of headphones when they rest onto the charging station; for the charging process to work, the said voltage source on board of the said pair of headphones needs to be of rechargeable type
that has a casing (separate from the casing of the said pair of headphones) comprising an electric cord that goes out to the wall power plug to power the electric charging circuit comprised in it
that has a charging circuit comprising a rectifying circuit that converts alternative current voltage to direct current voltage
that has a charging magnetic coil allowing the pair of headphones to get charged when deposited on it in the headphones rest location
that has a charging light indicator that, turns red when the voltage source on board of the pair of headphones is getting charged from the charging circuit, turns green when the voltage source on board of the pair of headphones is fully charged.
